(19) United States
(12) Patent Application Publication
(10) Pub. No.: US 2011/0085365 A1
(43) Pub. Date: Apr. 14, 2011

(54) SEMICONDUCTOR DEVICE

(75) Inventor: Chi Hwan JANG, Icheon-si (KR)

(73) Assignee: Hynix Semiconductor Inc., Icheon-si (KR)

(21) Appl. No.: 12/650,283

(22) Filed: Dec. 30, 2009

(30) Foreign Application Priority Data
Oct. 13, 2009 (KR) 10-2009-0097236

(51) Int. Cl. G11C 5/02

(52) U.S. Cl. 365/51

(57) ABSTRACT

A semiconductor device includes a substrate including a cell area and a sense amplifier area, a first bit line connected to a bit line contact of the cell area and a first contact of the sense amplifier area, and a second bit line located on the first bit line to overlap with the first bit line on a plan view and connected to a second contact of the sense amplifier area. The semiconductor device applies a folded bit line structure to a 6F2 structure so as to promote competitiveness of a net die, resulting in reduction of production costs. The semiconductor device implements various test patterns for defect analysis, wherein a conventional 6F2-layout open bit line has difficulty in using the test patterns, resulting in an increased production yield. The semiconductor device reduces noise of a sense amplifier, and performs mat-basis repairing, resulting in an increased production yield.

### CROSS-REFERENCE TO RELATED APPLICATION

The priority of Korean patent application No. 10-2009-0097236 filed on Oct. 13, 2009, the disclosure of which is hereby incorporated in its entirety by reference, is claimed.

### BACKGROUND OF THE INVENTION

1. Field of the Invention

The present invention relates to a semiconductor device, and more particularly to a semiconductor device for overcoming shortcomings of a folded bit line and an open bit line.

2. Background of the Invention

In recent times, many people and developers are conducting intensive research into a technology for increasing the number of net die so as to promote competitiveness in production costs. By such efforts, a semiconductor device structure is rapidly changing from a 8F2 cell array structure to a 6F2 or 4F2 cell array structure. The 6F2 cell array structure has received much attention recently since it can integrate a significantly more cells on the same area than the 8F2 cell array structure.

Generally, a folded bit line structure has been applied to the 8F2 cell array structure, and an open bit line structure has been applied to the 6F2 cell array structure. The folded bit line structure means that a bit line (BL) and a bit bar line (/BL) are arranged in parallel to each other in one direction of a sense amplifier, and the open bit line structure means that the bit line is spaced apart from the bit bar line at both sides of the sense amplifier.

In more detail, the folded bit line structure means that the bit line and the bit bar line are present in one memory block. In addition, a plurality of bit line pairs (each pair includes a bit line and a bit bar line) and a plurality of word lines intersect at a right angle (90 degrees) within the memory block, and a plurality of memory cells capable of storing data therein are arranged at intersection areas of the word lines and the bit line pairs in such a manner that each memory cell is arranged at an intersection of each bit line and each word line. Also, the sense amplifiers are located at both sides of the memory block. One sense amplifier located at one side of the memory block is connected to the bit line, and the other sense amplifier located at the other side of the memory block is connected to the bit bar line. A plurality of bit lines is connected to input/output (I/O) lines through a switching circuit. However, as a semiconductor memory device becomes highly integrated, the folded bit line structure is required to include all pairs of bit lines (wherein each pair is composed of one bit line and one bit bar line) in one memory block, and thus a large area is needed for installation of all bit line pairs. In addition, it also requires memory cells and peripheral circuits capable of writing and reading data in and from the memory cells to be highly integrated in the above-mentioned semiconductor memory device.

In addition, according to the open bit line structure, the bit line and the bit bar line, that are arranged to be adjacent to each other on the basis of the sense amplifier, are present in different memory blocks. A plurality of bit lines (or bit bar lines) and a plurality of word lines intersect at right angles within the memory block, and a plurality of memory cells capable of storing data therein are arranged at intersection areas of the bit lines (or bit bar lines) and the word lines in such a manner that each memory cell is arranged in an intersection between each bit line (or each bit bar line) and each word line. Also, one side of the sense amplifier is connected to the bit line, and the other side thereof is connected to the bit bar line. Accordingly, the sense amplifier is connected between the bit bar line and the bit line, and detects and amplifies a voltage difference between the bit line and the bit bar line.

Generally, word lines and bit lines are arranged perpendicular to each other in a memory cell array. Therefore, when the word lines are enabled, the voltage of the bit line is slightly increased due to coupling capacitance between the word line and the bit line. As a result, noise occurs in the bit line due to the coupling capacitance. However, since the bit line and the bit bar line contained in the open bit line structure are present in different memory blocks, no noise occurs in the bit line and the bit bar line.

In more detail, for example, in the case where only a word line contained in one of memory blocks arranged on the basis of the sense amplifier is enabled and a word line contained in the other memory block is not enabled, the coupling noise occurs in the bit line contained in the one memory block and no coupling noise occurs in the bit bar line contained in the other memory block, so that the bit line and the bit bar line have different noise environments. As a result, the sense amplifier has low sensitivity. In conclusion, the sense amplifier has difficulty in amplifying a minute voltage between the bit line and the bit bar line.

In addition, in the case of analyzing whether a defective part appears in the semiconductor device, the open bit line structure has difficulty in analyzing the defective part of the semiconductor device. In other words, the open bit line structure does not share the bit line sense amplifier, so that it has difficulty in implementing various test patterns for analyzing such a defective part due to the absence of a bit line isolation transistor. For example, the open bit line structure is unable to adopt a check board structure therein, and is also unable to implement a pattern such as an Unlimited Sensing Delay (USD) or the like.

### BRIEF SUMMARY OF THE INVENTION

Various embodiments of the present invention are directed to providing a semiconductor device that substantially obviates one or more problems due to limitations and disadvantages of the related art.

An object of the present invention is to provide a semiconductor device capable of solving the problems of a folded bit line structure applied to a conventional 8F2 structure and an open bit line structure applied to a 6F2 structure.

In accordance with an aspect of the present invention, a semiconductor device includes a semiconductor substrate including a cell area and a sense amplifier area, a first bit line formed on a first level, the first bit line electrically coupling a bit line contact in the cell area to a first contact in the sense amplifier area and a second bit line formed on a second level over the first level, the second bit line being electrically coupled to a second contact in the sense amplifier area, the second bit line being in parallel to the first bit line.

Preferably, the first contact and the second contact may be coupled to different active regions in the sense amplifier area.

Preferably, the first contact and the second contact may be arranged next to each other along a longitudinal direction of the first and second bit lines.

Preferably, the second bit line may be extended farther than the first bit line in a longitudinal direction toward the sense amplifier area so that it is connected to the second contact.

Preferably, the semiconductor device may further include a first isolation gate that is formed on the active region where is formed the first contact in the sense amplifier area.

Preferably, the semiconductor device may further include a first sensing contact that is spaced apart from the first contact by the first isolation gate.

Preferably, the semiconductor device may further include a second sensing contact connected to the active region where is formed the second contact in the sense amplifier area.

Preferably, the semiconductor device may further include a second isolation gate formed on the active region where is formed the second contact in the sense amplifier area.

Preferably, the second sensing contact that may be spaced apart from the second contact by the second isolation gate.

Preferably, the second sensing contact may be provided with substantially the same height as that of the first contact.

Preferably, the second sensing contact may be provided with substantially the same height as that of the second contact.

Preferably, the first contact and the second contact are adjacent to each other in a direction of minor axis of the active regions.

Preferably, the second bit line may have one end that is perpendicular to a longitudinal direction of the second bit line.

Preferably, the second bit line may have one end that is connected to the second contact.

Preferably, the semiconductor device may further include a third isolation gate for traversing a central part of the active regions.

Preferably, the semiconductor device may further include a third sensing contact that is spaced apart from the first contact by the third isolation gate.

Preferably, the semiconductor device may further include a fourth sensing contact that is spaced apart from the second contact by the third isolation gate.

### BRIEF DESCRIPTION OF THE DRAWINGS

FIG. 1a is a plan view illustrating a semiconductor device according to a first embodiment of the present invention.

FIG. 1b is a cross-sectional view illustrating a semiconductor device taken along the line y-y′ of FIG. 1a according to a first embodiment of the present invention.

FIG. 2 is a cross-sectional view illustrating a semiconductor device according to a second embodiment of the present invention.

FIG. 3 is a cross-sectional view illustrating a semiconductor device according to a third embodiment of the present invention.

FIG. 4a is a plan view illustrating a semiconductor device according to a fourth embodiment of the present invention.

FIG. 4a is a cross-sectional view illustrating a semiconductor device taken along the line y-y′ of FIG. 4a according to a fourth embodiment of the present invention.

FIG. 5a is a plan view illustrating a semiconductor device according to a fifth embodiment of the present invention.

FIG. 5b is a cross-sectional view illustrating a semiconductor device taken along the line y-y′ of FIG. 5a according to a fifth embodiment of the present invention.

### DESCRIPTION OF EMBODIMENTS

Reference will now be made in detail to the embodiments of the present invention, examples of which are illustrated in the accompanying drawings. Wherever possible, the same reference numbers will be used throughout the drawings to refer to the same or like parts.

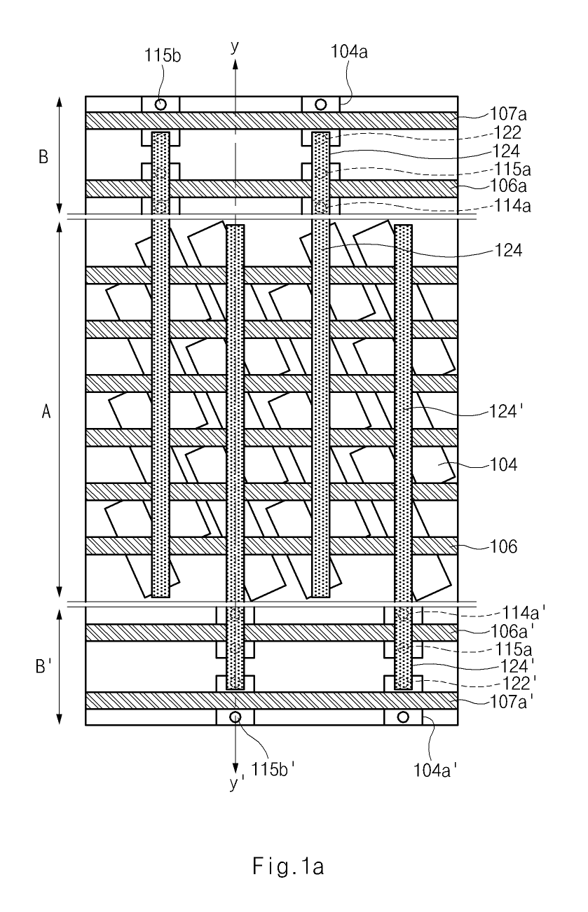

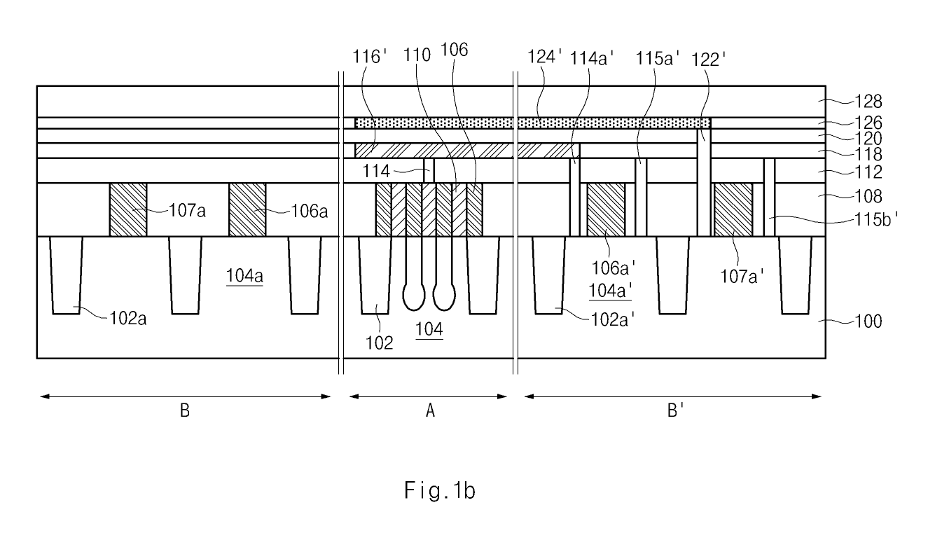

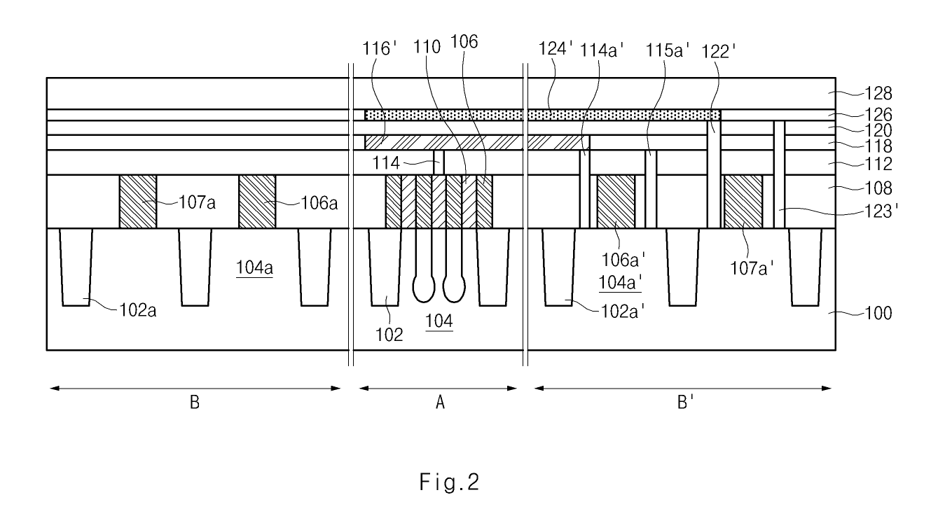

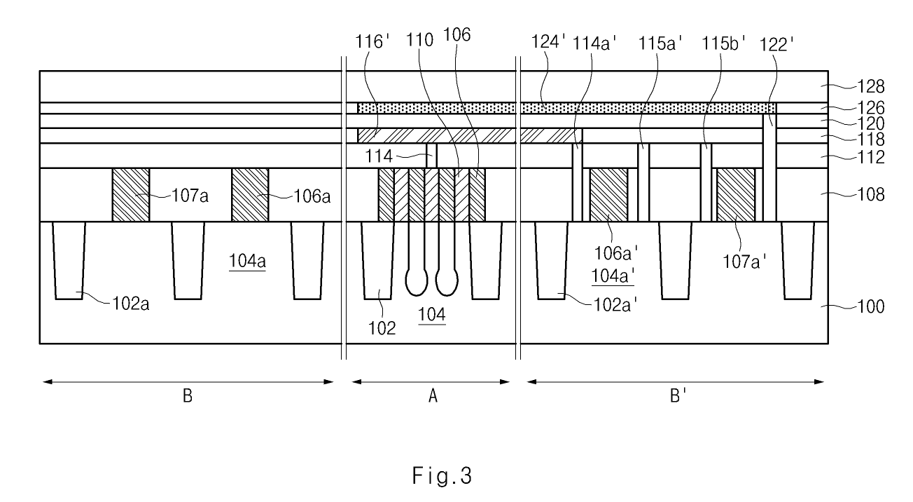

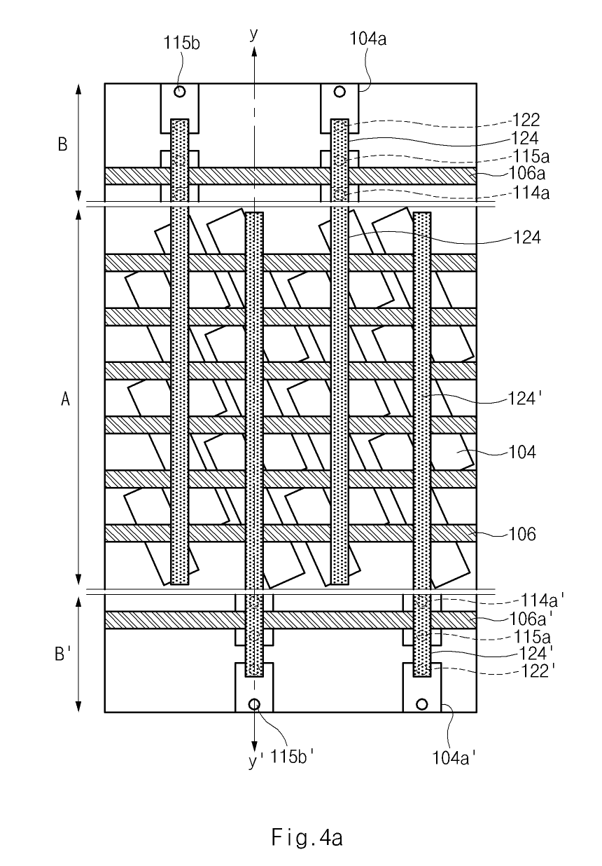

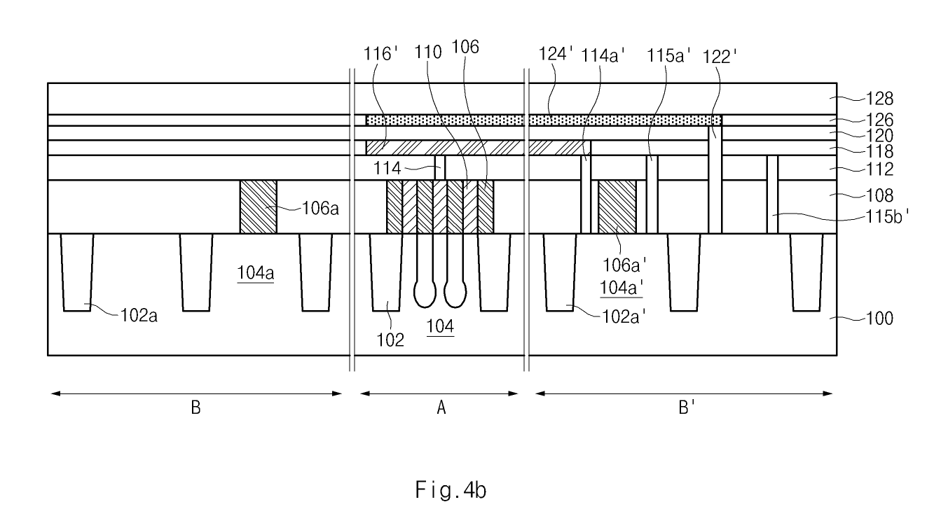

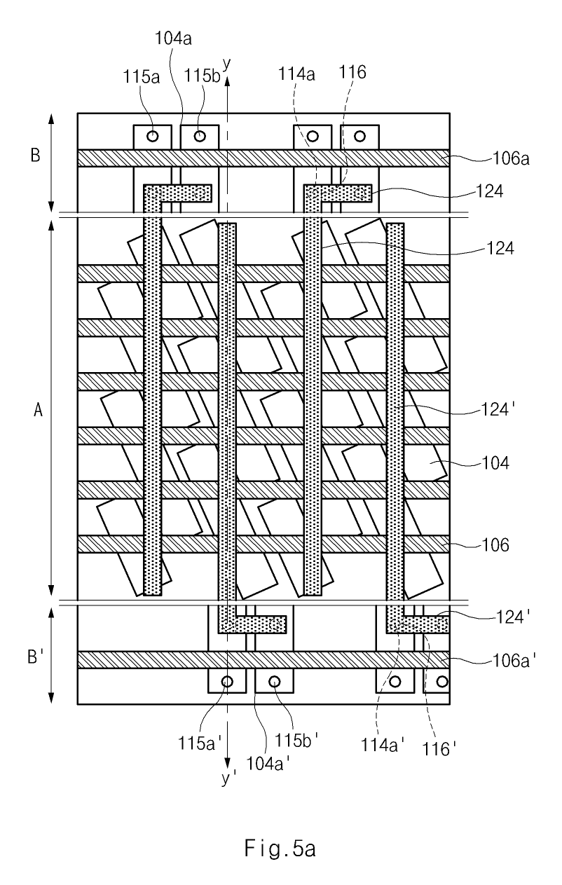

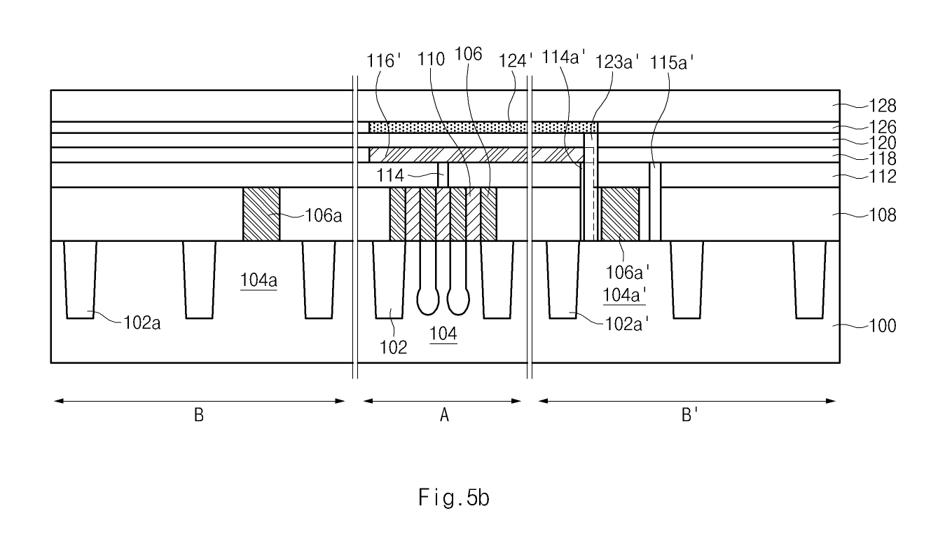

FIG. 1a is a plan view illustrating a semiconductor device according to a first embodiment of the present invention. FIG. 1b is a cross-sectional view illustrating a semiconductor device taken along the line y-y′ of FIG. 1a according to a first embodiment of the present invention. FIG. 2 is a cross-sectional view illustrating a semiconductor device according to a second embodiment of the present invention. FIG. 3 is a cross-sectional view illustrating a semiconductor device according to a third embodiment of the present invention. FIG. 4a is a plan view illustrating a semiconductor device according to a fourth embodiment of the present invention. FIG. 4b is a cross-sectional view illustrating a semiconductor device taken along the line y-y′ of FIG. 4a according to a fourth embodiment of the present invention. FIG. 5a is a plan view illustrating a semiconductor device according to a fifth embodiment of the present invention. FIG. 5b is a cross-sectional view illustrating a semiconductor device taken along the line y-y′ of FIG. 5a according to a fifth embodiment of the present invention.

Referring to FIG. 1a, the semiconductor device according to the present invention includes bit lines (Below 124, not shown), 124, (Below 124′, See FIG. 1b), and 124′, which have the same width and are spaced apart from one another by a predetermined distance. The bit line (Below 124, not shown) is connected to bit line contacts (not shown) of a cell area A, and is connected to an active region 104a of a sense amplifier area B. The bit line 124 is extended farther than the bit line (Below 124, not shown) in longitudinal direction toward the sense amplifier area B so that it is connected to the active region 104a of the sense amplifier area B. The bit line 116′ (See FIG. 1b) is connected to bit line contacts (not shown) of the cell area A, and is connected to an active region 104a′ of the sense amplifier area B′. The bit line 124′ is extended farther than the bit line 116′ (See FIG. 1b) in longitudinal direction toward the sense amplifier area B′ so that it is connected to the active region 104a′ of the sense amplifier area B′.

In this case, the bit lines 124 and 124′ is provided to extend farther than the bit lines (Below 124, not shown) and 116′ (See FIG. 1b) in longitudinal direction toward the sense amplifier area B,B′ in order to prevent short circuiting between the bit lines 124 and 124′ and the other bit lines (Below 124, not shown) and 116′ (See FIG. 1b) in the case where the bit lines 124 and 124′ are connected to the active regions 104a and 104a′. Preferably, each of the bit lines (Below 124, not shown) and 116′ (See FIG. 1b) may be a bit line (Bit), that is connected to the cell area A and the sense amplifier areas B and B′ and is associated with a cell operation. Preferably, each of the bit lines 124 and 124′ may be a reference bit line (Bit_Ref) for receiving a specific voltage.

In more detail, the bit lines (Below 124, not shown) and 116′ (See FIG. 1b) are connected to the sense amplifier areas B and B′, and allow electric charges applied to the contacts 114a and 114a′ to be transferred to other contacts 115a and 115a′ through isolation gates 106a and 106a′, so that the bit lines (Below 124, not shown) and 116′ (See FIG. 1b) are sensed through the contacts 115a and 115a′. The bit lines 124 and 124′ are connected to the sense amplifier areas B and B′, and allow electric charges applied to the contacts 122 and 122′ to be transferred to other contacts 115b and 115b′ through isolation gates 107a and 107a′, so that the contacts 115b and 115b′ can sense the bit lines 124 and 124′. In this case, the contacts 115a, 115a′, 115b, and 115b′ are adapted to sense the bit lines (Below 124, not shown), 116′ (See FIG. 1b), 124, and 124′, so that each of the contacts will hereinafter be referred to as a ‘sensing contact’ for convenience of description.

Preferably, the bit lines (Below 124, not shown), 116′ (See FIG. 1b), 124, and 124′ may have the same width. Preferably, the bit lines (Below 124, not shown) and 116′ (See FIG. 1b) may be spaced apart from each other by an interlayer insulating layer (not shown) located under the bit lines 124 and 124′, and may be overlapped with the bit lines 124 and 124′, so that only the bit lines 124 and 124′ are shown in the plan view of the semiconductor device. In this way, the reason why the bit lines (Below 124, not shown), 116′ (See FIG. 1b), 124, and 124′ have the same width and are arranged at upper and lower parts of the same position is to allow capacitances of the bit lines (Below 124, not shown) and 124 to be maximally equal to those of the bit lines 116′ (See FIG. 1b) and 124′. As a result, since the same coupling capacitance occurs in the bit lines (Below 124, not shown) and 124 and the other bit lines 116′ (See FIG. 1b) and 124′, the bit lines (Below 124, not shown) and 124 have the same noise environment as that of the other bit lines 116′ (See FIG. 1b) and 124′, so that it is prevented for the sensitivity of the sense amplifier to be decreased.

In other words, the present invention provides a folded bit line structure in which a bit line and a bit bar line respectively located at upper and lower parts are present in one memory block, whereas the related art provides the bit line and the bit bar line, that are present in different memory blocks while being arranged on the basis of the sense amplifier, by allowing different mats to share one sense amplifier.

FIG. 1B is a cross-sectional view illustrating the semiconductor device taken along the line y-y′ of FIG. 1a according to a first embodiment of the present invention.

Referring to FIG. 1b, the semiconductor device according to the present invention includes a gate 106 and isolation gates 106a, 107a, 106a′, and 107a′ on a semiconductor substrate 100 including a cell area A and sense amplifier areas B and B′. In this case, the isolation gate 106a′ of the sense amplifier area B′ is configured to sense the bit line 116′, and the isolation gate 107a′ is configured to sense the bit line 124′. At this time, although not shown in FIG. 1b, it is preferable that the isolation gate 106a contained in the sense amplifier area B be configured to sense the bit line (Below 124, not shown) and the isolation gate 107a be configured to sense the bit line 124.

In addition, the semiconductor device further includes a landing plug 110 buried in a contact hole (not shown) that exposes the active region 104 of the cell area A formed in the interlayer insulating layer 108 formed over the entire upper surface including the gates 106, 107a, 106a′, and 107a′. Also, the semiconductor further includes a bit line contact 114, that passes through the interlayer insulating layer 112 formed over the entire upper surface including the landing plug 110 and gates 106a, 107a, 106a′, and 107a′ and at the same time is buried in the contact hole (not shown) exposing the landing plug 110.

In addition, the semiconductor device further includes a contact 114a′ and a sensing contact 115a′, that are connected to the active region 104a′ of the sense amplifier area B′ and pass through the interlayer insulating layers 112 and 108. The semiconductor device further includes the bit line 116′ connected to both the top surface of the bit line contact 114 and the top surface of the contact 114a (See FIG. 1a). In this case, the contact 114a′ and the sensing contact 115a′ are spaced apart from each other on the basis of the isolation gate 106a′. Preferably, if the isolation gate 106a′ is enabled, the bit line 116′ is sensed through the sensing contact 115a′ by electric charges that have moved from the contact 114a′ to the sensing contact 115a′.

In addition, the semiconductor device includes a contact 122′ and another contact 115b′. The contact 122′ is connected to the active region 104a′ of the sense amplifier area B′ and passes through the interlayer insulating layers 120, 118, 112, and 108. The contact 115b′ passes through the interlayer insulating layers 112 and 108. The semiconductor device further includes the bit line 124′ connected to the contact 122′. In this case, the contact 122′ and the sensing contact 115b′ are spaced apart from each other on the basis of the isolation gate 107a′. Preferably, if the isolation gate 107a′ is enabled, the bit line 124′ is sensed through the sensing contact 115b′ by electric charges that have moved from the contact 122′ to the sensing contact 115b′.

Although not shown in FIG. 1b, the semiconductor device according to the present invention further includes a contact (not shown), that is connected to the active region 104a of the sense amplifier area B and passes through the interlayer insulating layers 112 and 108. The semiconductor device further includes not only the bit line contact 114 connected to the landing plug 110 of the cell area A, but also the bit line (Below 124, not shown) connected to the bit line contact 114 and the contact 114a (See FIG. 1a).

In addition, the semiconductor device includes the contact 122 (See FIG. 1a) and the bit line 124 (See FIG. 1a). The contact 122 passes through the interlayer insulating layers 120, 118, 112, and 108 and is connected to the sense amplifier area B. The bit line 124 is connected to the top surface of the contact 122 and is formed on the interlayer insulating layer 120. In this case, it is preferable that the bit line (Below 124, not shown) and the bit line 124 (See FIG. 1a) be vertically spaced apart from each other by the interlayer insulating layer 120, have the same width, and be located at the same position in such a manner that the bit line (Below 124, not shown) overlaps with the bit line 124 in the plan view of the semiconductor device. In this way, the reason why the bit lines (Below 124, not shown) and 124 (See FIG. 1a) have the same width and are arranged at upper and lower parts of the same position is to allow capacitances of the bit lines (Below 124, not shown) and 124 to be maximally equal to each other.

As described above, the semiconductor device according to the present invention achieves a folded bit line structure in which all the bit lines (Below 124, not shown), 116′, 124, and 124′ are present in one memory block.

Besides, the semiconductor device according to the present invention is not limited only to the above-mentioned structure, and can be modified into other structures as necessary. In more detail, if two isolation gates are present in the sense amplifier area, the semiconductor device structure can be modified according to a bit line structure connected to the active region of the sense amplifier area, and as such detailed descriptions thereof will hereinafter be described with reference to FIGS. 2 and 3.

FIG. 2 is a cross-sectional view illustrating a semiconductor device according to a second embodiment of the present invention. Referring to FIG. 2, the semiconductor device according to a second embodiment of the present invention includes a gate 106 and isolation gates 106a, 107a, 106a′, and 107a′ on a semiconductor substrate 100 including a cell area A and sense amplifier areas B and B′. In this case, the isolation gate 106a′ of the sense amplifier area B′ is configured to sense the bit line 116′, and the isolation gate 107a′ is configured to sense the bit line 124′. At this time, although not shown in FIG. 2, it is preferable that the isolation gate 106a (See FIG. 1a) contained in the sense amplifier area B be configured to sense the bit line (Below 124 (See FIG. 1a), not shown) and the isolation gate 107a (See FIG. 1a) be configured to sense the bit line 124 (See FIG. 1a).

In addition, the semiconductor device further includes a landing plug 110 buried in a contact hole (not shown) that exposes the active region 104 of the cell area A formed in the interlayer insulating layer 108 formed over the entire upper surface including the gates 106, 107a, 106a′, and 107a′. Also, the semiconductor further includes a bit line contact 114, that passes through the interlayer insulating layer 112 formed over the entire upper surface including the landing plug 110 and gates 106a, 107a, 106a′, and 107a′ and at the same time is buried in the contact hole (not shown) exposing the landing plug 110.

In addition, the semiconductor device further includes a contact 114a′ and a sensing contact 115a′, that are connected to the active region 104a′ of the sense amplifier area B′ and pass through the interlayer insulating layers 112 and 108. The semiconductor device further includes the bit line 116′ connected to both the top surface of the bit line contact 114 and the top surface of the contact 114a. In this case, the contact 114a′ and the sensing contact 115a′ are spaced apart from each other on the basis of the isolation gate 106a′. Preferably, if the isolation gate 106a′ is enabled, the bit line 116′ is sensed through the sensing contact 115a′ by electric charges that have moved from the contact 114a′ to the sensing contact 115a′.

In addition, the semiconductor device includes a contact 122′, a sensing contact 123′, and a bit line 124′. The contact 122′ and the sensing contact 123′ are connected to the active region 104a′ of the sense amplifier area B′ and pass through the interlayer insulating layers 120, 118, 112, and 108, and the bit line 124′ is connected to the contact 122′. In this case, the contact 122′ and the sensing contact 123′ are spaced apart from each other on the basis of the isolation gate 107a′. Preferably, if the isolation gate 107a′ is enabled, the bit line 124′ is sensed through the sensing contact 123′ by electric charges that have moved from the contact 122′ to the sensing contact 123′. In this case, since the contact 123′ is not formed on the same layer as those of the bit line contact 114 and the contacts 114a′ and 115a′, it is possible to guarantee the area of a pattern formed on the same layer as those of the contacts 114a′ and 115a′, so that the contact 123′ can be easily designed.

FIG. 3 is a cross-sectional view illustrating a semiconductor device according to a third embodiment of the present invention. Referring to FIG. 3, the semiconductor device according to a third embodiment of the present invention includes a gate 106 and isolation gates 106a, 107a, 106a′, and 107a′ on a semiconductor substrate 100 including a cell area A and sense amplifier areas B and B′. In this case, the isolation gate 106a′ of the sense amplifier area B′ is configured to sense the bit line 116′, and the isolation gate 107a′ is configured to sense the bit line 124′. At this time, although not shown in FIG. 3, it is preferable that the isolation gate 106a (See FIG. 1a) contained in the sense amplifier area B be configured to sense the bit line (Below 124 (See FIG. 1a), not shown) and the isolation gate 107a (See FIG. 1a) be configured to sense the bit line 124.

In addition, the semiconductor device further includes a landing plug 110 buried in a contact hole (not shown) that exposes the active region 104 of the cell area A formed in the interlayer insulating layer 108 formed over the entire upper surface including the gates 106, 107a, 106a′, and 107a′. Also, the semiconductor further includes a bit line contact 114, that passes through the interlayer insulating layer 112 formed over the entire upper surface including the landing plug 110 and gates 106a, 107a, 106a′, and 107a′ and at the same time is buried in the contact hole (not shown) exposing the landing plug 110. In addition, the semiconductor device further includes a contact 114a′ and a sensing contact 115a′, that are connected to the active region 104a′ of the sense amplifier area B′ and pass through the interlayer insulating layers 112 and 108. The semiconductor device further includes the bit line 116′ connected to both the top surface of the bit line contact 114 and the top surface of the contact 114a. In this case, the contact 114a′ and the sensing contact 115a′ are spaced apart from each other on the basis of the isolation gate 106a′. Preferably, if the isolation gate 106a′ is enabled, the bit line 116′ is sensed through the sensing contact 115a′ by electric charges that have moved from the contact 114a′ to the sensing contact 115a′.

In addition, the semiconductor device includes a contact 122′ and a bit line 124′. The contact 122′ is connected to the active region 104a′ of the sense amplifier area B′ and passes through the interlayer insulating layers 120, 118, 112, and 108, and the bit line 124′ is connected to the contact 122′. In this case, the contact 122′ and the sensing contact 115b′ are spaced apart from each other on the basis of the isolation gate 107a′. Preferably, if the isolation gate 107a′ is enabled, the bit line 124′ is sensed through the sensing contact 115b′ by electric charges that have moved from the contact 122′ to the sensing contact 115b′. In this case, since the sensing contact 115b′ is arranged to be adjacent to the sensing contact 115a′ on the basis of a device isolation layer 102a′, a difference in capacitance between one sensing contact 115a′ and the other sensing contact 115b′ is very small, so that the influence of noise caused by a latch transistor (not shown) contained in the sense amplifier area B′ can be decreased.

Meanwhile, the semiconductor device according to the present invention is not limited only to the above-mentioned structures and can also be modified to other structures as necessary. In other words, if one isolation gate is present in the sense amplifier area, the semiconductor device according to the present invention can be modified to others according to a bit line structure connected to the active region of the sense amplifier area, and as such a detailed description thereof will hereinafter be described in detail.

FIG. 4a is a plan view illustrating a semiconductor device according to a fourth embodiment of the present invention. Referring to FIG. 4a, the semiconductor device according to the fourth embodiment of the present invention includes bit lines (Below 124, not shown), 124, 116′ (See FIG. 4b), and 124′, which have the same width and are spaced apart from one another by a predetermined distance. The bit line (Below 124, not shown) is connected to bit line contacts (not shown) of a cell area A, and is connected to an active region 104a of a sense amplifier area B. The bit line 124 is extended farther than the bit line (Below 124, not shown) in longitudinal direction toward the sense amplifier area B so that it is connected to the active region 104a of the sense amplifier area B. The bit line 116′ (See FIG. 4b) is connected to bit line contacts (not shown) of the cell area A, and is connected to an active region 104a′ of the sense amplifier area B′. The bit line 124′ is extended farther than the bit line 116′ (See FIG. 4b) in longitudinal direction toward the sense amplifier area B′ so that it is connected to the active region 104a′ of the sense amplifier area B′.

In this case, the reason why the bit lines 124 and 124′ are extended farther than the bit lines (Below 124, not shown) and 116′ (See FIG. 4b) in longitudinal direction toward the sense amplifier area B,B′ is to prevent short circuiting between the bit lines 124 and 124′ and the other bit lines (Below 124, not shown) and 116′ (See FIG. 4b) in the case where the bit lines 124 and 124′ are connected to the active regions 104a and 104a′. Preferably, each of the bit lines (Below 124, not shown) and 116′ (See FIG. 4b) may be a bit line (Bit), that is connected to the cell area A and the sense amplifier areas B and B′ and is associated with a cell operation. Preferably, each of the bit lines 124 and 124′ may be a reference bit line (Bit_Ref) for receiving a specific voltage.

In more detail, the bit lines (Below 124, not shown) and 116′ (See FIG. 4b) are connected to the sense amplifier areas B and B′, and allow electric charges applied to the contact 114a′ to be transferred to the contact 115a′ through isolation gates 106a and 106a′. Preferably, the bit lines 124 and 124′ are connected to the sense amplifier areas B and B′ through the contact 122′, so that the bit lines 124 and 124′ can be directly sensed.

Preferably, the bit lines (Below 124, not shown), 116′ (See FIG. 4b), 124, and 124′ may have the same width. Preferably, the bit lines (Below 124, not shown) and 116′ (See FIG. 4b) may be spaced apart from each other by an interlayer insulating layer (not shown) located under the bit lines 124 and 124′, and may be overlapped with the bit lines 124 and 124′, so that only the bit lines 124 and 124′ are shown in the plan view of the semiconductor device. In this way, the reason why the bit lines (Below 124, not shown), 116′ (See FIG. 4b), 124, and 124′ have the same width and are arranged at upper and lower parts of the same position is to allow capacitances of the bit lines 116 and 124 to be maximally equal to those of the bit lines 116′ (See FIG. 4b) and 124′. As a result, since the same coupling capacitance occurs in the bit lines (Below 124, not shown) and 124 and the other bit lines 116′ (See FIG. 4b) and 124′, the bit lines (Below 124, not shown) and 124 have the same noise environment as that of the other bit lines 116′ (See FIG. 4b) and 124′, so that it is prevented for the sensitivity of the sense amplifier to be decreased.

In other words, the present invention provides a folded bit line structure in which a bit line and a bit bar line respectively located at upper and lower parts are present in one memory block, whereas the related art provides the bit line and the bit bar line, that are present in different memory blocks while being arranged on the basis of the sense amplifier, by allowing different mats to share one sense amplifier.

FIG. 4b is a cross-sectional view illustrating a semiconductor device taken along the line y-y′ of FIG. 4a according to a fourth embodiment of the present invention. Referring to FIG. 4b, the semiconductor device according to the fourth embodiment of the present invention includes a gate 106 and isolation gates 106a and 106a′ on a semiconductor substrate 100 including a cell area A and sense amplifier areas B and B′. In this case, the isolation gate 106a′ of the sense amplifier area B′ is configured to sense the bit line 116′. At this time, although not shown in FIG. 4b, it is preferable that the isolation gate 106a (See FIG. 4a) contained in the sense amplifier area B be configured to sense the bit line (Below 124, not shown).

In addition, the semiconductor device further includes a landing plug 110 buried in a contact hole (not shown) that exposes the active region 104 of the cell area A formed in the interlayer insulating layer 108 formed over the entire upper surface including the gates 106 and 106a′. Also, the semiconductor further includes a bit line contact 114, that passes through the interlayer insulating layer 112 formed over the entire upper surface including the landing plug 110 and gates 106a and 106a′ and at the same time is buried in the contact hole (not shown) exposing the landing plug 110.

In addition, the semiconductor device further includes a contact 114a′ and a sensing contact 115a′, that are connected to the active region 104a′ of the sense amplifier area B′ and pass through the interlayer insulating layers 112 and 108. The semiconductor device further includes the bit line 116′ connected to both the top surface of the bit line contact 114 and the top surface of the contact 114a. In this case, the contact 114a′ and the sensing contact 115a′ are spaced apart from each other on the basis of the isolation gate 106a′. Preferably, if the isolation gate 106a′ is enabled, the bit line 116′ is sensed through the sensing contact 115a′ by electric charges that have moved from the contact 114a′ to the sensing contact 115a′.

In addition, the semiconductor device includes a contact 122′, a sensing contact 115b′, and a bit line 124′. The contact 122′ is connected to the active region 104a′ of the sense amplifier area B′ and passes through the interlayer insulating layers 120, 118, 112, and 108. The sensing contact 115b′ passes through the interlayer insulating layers 112 and 108. The bit line 124′ is formed on the interlayer insulating layer 120, and is connected to the contact 122′. In this case, it is preferable that a reference voltage be applied to the sensing contact 115b′ so that a constant voltage be applied to the bit line 124′ through the contact 122′. Therefore, although only one isolation gate is contained in the sense amplifier area, there is no difficulty in sensing the bit line and it is prevented for the sense amplifier area to be complicated, so that the present invention can form the same isolation gate structure as that of a conventional folded sense amplifier.

FIG. 5a is a plan view illustrating a semiconductor device according to a fifth embodiment of the present invention. Referring to FIG. 5a, the semiconductor device according to the fifth embodiment of the present invention includes bit lines 116, 124, 116′, and 124′, which have the same width and are spaced apart from one another by a predetermined distance. The bit line 116 is connected to bit line contacts (not shown) of a cell area A, and is connected to the contact 114a formed on the active region 104a of a sense amplifier area B. The bit line 124 is connected to the contact 123a contained in the active region 104a that neighbors with the other active region 104a connected to the bit line 116, and the end of the bit line 124 is arranged perpendicular to a longitudinal direction of the bit line 116 and is configured in a form of a [symbol] -shape or an inverted [symbol] -shape (i.e., [symbol] -shape). The bit line 116′ is connected to bit line contacts (not shown) of the cell area A, and is also connected to the contact 114a′ formed on the active region 104a′ of the sense amplifier area B′. The bit line 124′ is connected to the contact 123a′ contained in the active region 104a′ that neighbors with the other active region 104a′ connected to the bit line (Below 124, not shown), and the end of the bit line 124 is arranged perpendicular to a longitudinal direction of the bit line 116′ and is configured in a form of a [symbol] -shape or an inverted [symbol] -shape (i.e., [symbol] -shape in this embodiment).

In this case, preferably, each of the bit lines 116 and 116′ may be a bit line (Bit), that is connected to the cell area A and the sense amplifier areas B and B′ and is associated with a cell operation. Preferably, each of the bit lines 124 and 124′ may be a reference bit line (Bit_Ref) for receiving a specific voltage.

In more detail, the bit lines 116 and 116′ are connected to the sense amplifier areas B and B′, and allow electric charges applied to the contact 114a′ to be transferred to the contacts 115a′ and 115a′ through isolation gates 106a and 106a′. Preferably, the bit lines 124 and 124′ may allow electric charges applied to the contacts 123a and 123a′ to be transferred to the sensing contacts 115b and 115b′ through the isolation gates 106 and 106a, so that the bit lines 124 and 124′ be directly sensed.

Preferably, the bit lines 116, 116′, 124, and 124′ may have the same width. Preferably, the bit lines 116 and 116′ may be spaced apart from each other by an interlayer insulating layer (not shown) located under the bit lines 124 and 124′, and may be overlapped with the bit lines 124 and 124′, so that only the bit lines 124 and 124′ are shown in the plan view of the semiconductor device.

In this way, the reason why the bit lines 116, 116′, 124, and 124′ have the same width and are arranged at upper and lower parts of the same position is to allow capacitances of the bit lines 116 and 124 to be maximally equal to those of the bit lines 116′ and 124′. As a result, since the same coupling capacitance occurs in the bit lines 116 and 124 and the other bit lines 116′ and 124′, the bit lines 116 and 124 have the same noise environment as in the other bit lines 116′ and 124′, so that it is prevented for the sensitivity of the sense amplifier to be decreased.

In other words, the present invention provides a folded bit line structure in which a bit line and a bit bar line respectively located at upper and lower parts are present in one memory block, whereas the related art provides the bit line and the bit bar line, that are present in different memory blocks while being arranged on the basis of the sense amplifier, by allowing different mats to share one sense amplifier.

FIG. 5b is a cross-sectional view illustrating a semiconductor device taken along the line y-y′ of FIG. 5a according to a fifth embodiment of the present invention. Referring to FIG. 5b, the semiconductor device according to the fifth embodiment of the present invention includes a gate 106 and isolation gates 106a and 106a′ on a semiconductor substrate 100 including a cell area A and sense amplifier areas B and B′. In this case, the isolation gate 106a′ of the sense amplifier area B′ is configured to sense the bit line 116′. At this time, although not shown in FIG. 5b, it is preferable that the isolation gate 106a (See FIG. 5a) contained in the sense amplifier area B be configured to sense the bit line 116.

In addition, the semiconductor device further includes a landing plug 110 buried in a contact hole (not shown) that exposes the active region 104 of the cell area A formed in the interlayer insulating layer 108 formed over the entire upper surface including the gates 106 and 106a′. Also, the semiconductor further includes a bit line contact 114, that passes through the interlayer insulating layer 112 formed over the entire upper surface including the landing plug 110 and gates 106a and 106a′ and at the same time is buried in the contact hole (not shown) exposing the landing plug 110.

In addition, the semiconductor device further includes a contact 114a′ and a sensing contact 115a′, that are connected to the active region 104a′ of the sense amplifier area B′ and pass through the interlayer insulating layers 112 and 108. In this case, the contact 114a′ and the sensing contact 115a′ are spaced apart from each other on the basis of the isolation gate 106a′. The semiconductor device further includes the bit line 116′ connected to the top surface of the bit line contact 114 and the top surface of the contact 114a′.

Also, the semiconductor device includes a contact 123a′, a sensing contact 115b′ (see FIG. 5a), and a bit line 124′. The contact 123a′ and the sensing contact 115b′(see FIG. 5a) are connected to the active region 104a′ that neighbors with the other active region 104a′ connected to the contact 114a′, and pass through the interlayer insulating layers 120, 118, 112, and 108, so that the contact 123a′ and the sensing contact 115b′ (see FIG. 5a) are spaced apart from each other on the basis of the isolation gate 106a. The bit line 124′ is connected to the contact 123a′, so that the end of the bit line 124′ is arranged perpendicular to a longitudinal direction of the bit line 116′.

In this case, although the contacts 114a′ and 123a′ are connected to the same position of the neighboring active regions, it should be noted that the contacts 114a′ is slightly spaced apart from the other contact 123a′ for convenience of description and better understanding of the present invention.

Preferably, if the isolation gate 106a′ is enabled, the bit line 116′ is sensed through the sensing contact 115a′ by electric charges that have moved from the contact 114a′ to the sensing contact 115a′, and the bit line 124′ is sensed through the sensing contact 115b′ due to the electric charges having moved from the contact 123a′ to the sensing contact 115b′.

As apparent from the above description, the present invention applies the folded bit line structure to the 6F2 structure so as to promote competitiveness of a net die, resulting in reduction of production costs. In addition, the present invention can implement various test patterns for defect analysis, wherein a conventional 6F2-layout open bit line has difficulty in using the test patterns, resulting in an increased production yield of the semiconductor device. Also, the present invention can reduce noise of the sense amplifier, and can repair the semiconductor device on a basis of a mat, resulting in an increased production yield.

In other words, the semiconductor device according to the embodiments of the present invention applies the folded bit line structure to the 6F2 structure, so that it can overcome limitations or problems caused by the open bit line structure of the related art, resulting in an increased production yield. In addition, the present invention includes the isolation gate in the sense amplifier area, so that it can implement a test pattern that is not applied to the open bit line structure, resulting in increased production yield of the semiconductor device.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A semiconductor device comprising:
a semiconductor substrate including a cell area and a sense amplifier area;
a first bit line formed on a first level, the first bit line electrically coupling a bit line contact in the cell area to a first contact in the sense amplifier area; and
a second bit line formed on a second level over the first level, the second bit line being electrically coupled to a second contact in the sense amplifier area, the second bit line being in parallel to the first bit line.

2. The semiconductor device according to claim 1, wherein the first contact and the second contact are coupled to different active regions in the sense amplifier area.

3. The semiconductor device according to claim 2, wherein the first contact and the second contact are arranged next to each other along a longitudinal direction of the first and second bit lines.

4. The semiconductor device according to claim 3 wherein the second bit line is extended farther than the first bit line in a longitudinal direction toward the sense amplifier area so that it is connected to the second contact.

5. The semiconductor device according to claim 3, further comprising a first isolation gate formed on the active region where is formed the first contact in the sense amplifier area

6. The semiconductor device according to claim 5, further comprising a first sensing contact that is spaced apart from the first contact by the first isolation gate.

7. The semiconductor device according to claim 2, further comprising a second sensing contact connected to the active region where is formed the second contact in the sense amplifier area.

8. The semiconductor device according to claim 7, further comprising a second isolation gate formed on the active region where is formed the second contact in the sense amplifier area.

9. The semiconductor device according to claim 8, wherein the second sensing contact that is spaced apart from the second contact by the second isolation gate.

10. The semiconductor device according to claim 9, wherein the second sensing contact is provided with substantially the same height as that of the first contact.

11. The semiconductor device according to claim 9, wherein the second sensing contact is provided with substantially the same height as that of the second contact.

12. The semiconductor device according to claim 2, wherein the first contact and the second contact are adjacent to each other in a direction of minor axis of the active regions.

13. The semiconductor device according to claim 12, wherein the second bit line has one end that is perpendicular to a longitudinal direction of the second bit line.

14. The semiconductor device according to claim 13, wherein the second bit line has one end that is connected to the second contact.

15. The semiconductor device according to claim 12, further comprising a third isolation gate for traversing a central part of the active regions.

16. The semiconductor device according to claim 15, further comprising a third sensing contact that is spaced apart from the first contact by the third isolation gate.

17. The semiconductor device according to claim 15, further comprising a fourth sensing contact that is spaced apart from the second contact by the third isolation gate.
